(19) United States
(12) Patent Application Publication
(10) Pub. No.: US 2007/0206400 A1
(43) Pub. Date: Sep. 6, 2007

(54) WRITE PROTECTION FOR COMPUTER LONG-TERM MEMORY DEVICES WITH WRITE-ONCE READ-MANY BLOCKING

(76) Inventors: Steven Bress, Germantown, MD (US); Daniel Bress, Germantown, MD (US); Mark Joseph Menz, Folsom, CA (US)

Correspondence Address: Steve Bress, 7851-C Beechcraft Avenue, Gaithersburg, MD, 20879, US

(21) Appl. No.: 11/623,060

(22) Filed: Jan. 13, 2007

Related U.S. Application Data
(60) Provisional application No. 60/766,382, filed on Jan. 15, 2006.

(51) Int. Cl. G11C 17/00

(52) U.S. Cl. 365/94

(57) ABSTRACT

A protection device provides write-once, read many capabilities for computer long-term storage devices, such as hard drives. The blocking device is placed between a host computer and a storage device. The blocking device intercepts communications between the host and the storage device and examines any commands from the host to the storage device. Certain commands, such as commands that may modify the storage device, may be discarded. Additionally, commands that may modify the state of previously written storage areas on the storage device may be discarded.

### RELATED APPLICATION

This application claims priority under 35 U.S.C. .sctn. 119 based on U.S. Provisional Application No. 60/766382, filed Jan. 15, 2006, the disclosure of which is incorporated herein by reference.

### BACKGROUND OF THE INVENTION

The present invention relates to computer memory devices and, more specifically, to mechanisms for controlling user access to the memory device to write-once, read-many.

### DESCRIPTION OF RELATED ART

There is a need in the art for a high-speed storage device that can permanently store data without the possibility of it being accidentally altered (write protect). Government regulations such as the Sarbanes-Oxley Act of 2002, the Federal Information Security Management Act (FISMA) of 2003 and the Health Insurance Portability and Accountability Act of 1996 (HIPAA), among others legislate data storage and security. These acts mandate that important data be accessible without any chance of being accidentally modified.

There is an additional need in the art for occasionally selectively deleting a subset of data normally protected as above. An example of this may be confidential personal information stored by an insurance company about an individual who is no longer a customer.

There is an additional need in the art to create a “snapshot” copy of the data stored on the long-term storage device, representing the exact state of the device including its data at the time of the snapshot. This could be accomplished by simply coping the data to another long-term storage device, however this would be a slow and costly solution.

Optical drives with write once media are not fast devices. In addition, an optical drive is either write once or rewriteable. If it is write once media, it is unchangeable and purged information may be recovered. A hard drive is a very fast device, but does not have any method of protection for the data.

Write protection techniques that are based on software protection of the drive are known in the art. In general, these techniques involve the installation of software that modifies the read/write parameters of the system. One disadvantage of these techniques is that they tend to be operating system specific. This creates the potential burden of properly installing, updating, and operating the software. Additionally, software protection is vulnerable to malicious attack. Additionally, these systems must be configured correctly and maintained correctly to properly protect data.

Other write protection devices known in the art depend on various mechanisms to protect the data from modification such as Storage Area Network (SAN) or Network Attached Storage (NAS) solutions. These devices rely on passwords and the like. They are vulnerable to malicious attacks. Additionally, these systems must be configured correctly and maintained correctly to properly protect data.

Accordingly, there is a need in the art for mechanisms for controlling user access to a memory device, such as a disk drive, to write-once, read-many.

### SUMMARY OF THE INVENTION

Systems and methods consisted with the present invention address these and other needs by providing for a blocking device that is physically inserted between a host computer and a storage device, wherein the logic and circuitry is configured to restrict access to the storage device to write-once, read-many.

One aspect of the invention is directed to a blocking device including a plurality of elements. Specifically, the blocking device includes an interface emulator configured to emulate an interface presented by a storage device and an interface for connecting to a storage device. Additionally, the blocking device includes logic and circuitry coupled to the interface emulator and the interface. The logic and circuitry maintains information on areas written to on the storage device. The logic and circuitry examines write commands received through the interface emulator that are generated by a host and intended for the storage device and allows write commands to areas of the storage device that have not previously been written to. Additionally the logic and circuitry drops commands that match a predetermined set of commands. The logic and circuitry allows non-matching commands to pass to the storage device via the interface.

Another aspect of the invention is that it may be operating system independent, thus no special drivers would be required and a trained operator would not be required to install it. A key observation is that the present invention is easy to deploy, unlike other systems, which need highly trained operators. Additionally, once our present invention is deployed it is maintenance free.

Another aspect of the invention is that if the invention were to malfunction, the invention would block all write attempts to the storage device.

Optical Read-Write drives are slow and expensive. All current operating systems have Optical Drive drivers. Therefore it may be desired to present our current invention to a host as an Optical Read-Write drive for the purposes of making our invention operating system independent. Thus, another aspect of the invention is to identify itself as an optical drive to a host.

There are occasions where it may be desired to take a “snap shot” of the data on a storage device, such as in a lawsuit or government investigation. There are obvious benefits to being able to acquire this “snap shot” in a fast and inexpensive manner. Therefore, another aspect of the invention is to make use of the list of areas written on the storage device that is maintained by the logic and circuitry for this purpose. Note that our present invention can provide absolute write protection, so this fast and inexpensive solution is compatible to a long and expensive disk copy.

If a full drive copy is required, there is an obvious benefit that this copy as efficient would be beneficial. Therefore another aspect of the invention provides for removable storage devices.

A key component of our current invention is the maintenance of information on areas written to the storage device. Other aspects of the invention provide various methods of securely maintaining this information.

There may be occasions where it is necessary to delete data. However, the ability to delete data must be as limited (secure) as possible. Therefore it is another aspect of the invention that only a host connected to our invention through an additional interface be permitted to issue certain commands, such as delete. Thus, the storage device may be available for multiple individuals to write-once, read many through one interface, but only an individual using a host with access to an additional interface would be able to delete data.

In order to make the present invention as cost-efficient as possible it may be desirable to connect to multiple storages devices. Thus another aspect of the invention is multiple interface emulators configured to emulate an interface presented by a host.

Interfaces have a limit on bandwidth. It may be desirable to transfer information to and from a storage device faster than this limit. Therefore another aspect of the invention is multiple interface emulators configured to emulate an interface presented by a storage device.

Systems and methods for protecting data may be required to be certified by an agency such as the United States Federal Government. Additionally this system and method may be required to be defended in a court of law. Therefore another aspect of the invention is a device that can pass a certifying process.

### BRIEF DESCRIPTION OF THE DRAWINGS

The accompanying drawings, which are incorporated in and constitute a part of this specification, illustrate the invention and, together with the description, explain the invention. In the drawings,

FIG. 1 is a diagram illustrating a write-once, read-many blocking device consistent with concepts of the invention;

FIG. 2 is a block diagram illustrating the write-once, read-many blocking device of FIG. 2 in more detail;

FIG. 3 is diagram illustrating an example of a pre-written sector of data;

FIG. 4 is a flow chart illustrating logic flow of the preferred embodiment;

FIG. 5 is a diagram illustrating a method for tracking sectors written to the storage device.

### DETAILED DESCRIPTION

The following detailed description of the invention refers to the accompanying drawings. The same reference numbers in different drawings identify the same or similar elements. Also, the following detailed description does not limit the invention. Instead, the scope of the invention is defined by the appended claims and equivalents.

A write-once, read-many blocking device is described herein that maintains written area information and blocks certain operations, such as read or write operations, as they are transmitted to a storage device. The blocking device 103 is physically inserted between a host computer system 101 and storage device 105 and is transparent to the host and the storage device. Written area information relates to tracking what areas on the storage device have been written to. This information may be kept in various forms, such as a list, a map, or simply the last area written to (if all information is written sequentially) among other methods. One skilled in the art would recognize that keeping information on areas not written to on the storage device would be equally effective.

The storage device may be any type of long-term non-volatile memory device. For example, the storage device may be a hard disk drive or compact flash memory. In one implementation, the storage device uses an Integrated Drive Electronics (IDE) interface. An IDE interface is a well known electronic interface that is frequently used to connect a computer's motherboard and disk drive. In IDE drives, the disk drive controller is built into the physical case of the disk drive. The IDE interface provides a relatively high level interface between the motherboard and the disk drive.

Although concepts consistent with the present invention are primarily described herein in relation to an IDE magnetic hard disk drive, these concepts may be implemented with other types of IDE media, such as flash memory with an IDE interface. Flash memories are a special type of semiconductor random access memory that retains its data after power has been removed from the system. Other types of media useable with an IDE interface include magnetic tape and optical media, such as a compact disc (CD) and a digital versatile disc (DVD). In addition to the IDE interface, concepts consistent with the invention may be applied in a straightforward manner to other types of high level storage interfaces, such as the well known Small Computer System Interface (SCSI) standard.

For the sake of clarity the remaining description herein will be described with reference to an IDE magnetic hard drive, although, as mentioned above, the concepts of the invention are not limited to such drives. One skilled in the art would appreciate that other modern long-term storage device interfaces share similar functionality that could be incorporated into the concepts described herein.

Applicant's U.S. Pat. No. 6,813,682 Bress et al., teaches the basics of write blocking. The following discussion concerns hardware and software additions, deletions and modifications of the systems and methods taught therein for a write-once, read-many write blocker. Thus how to modify capabilities information from a storage device and the like, is mentioned but not taught here, as it is taught in detail in Bress et al.

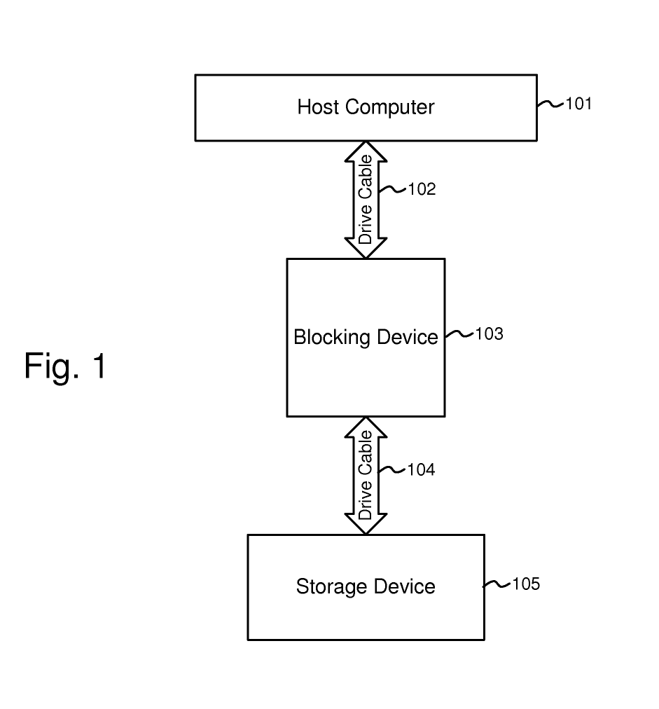

FIG. 1 is block diagram illustrating an exemplary implementation of blocking device 103. The blocking device includes microprocessor 210 and programmable logic device (PLD) 290. Microprocessor 210 may be an embedded processor, such as the 80386 EX embedded processor manufactured by Intel Corporation, of Santa Clara, Calif. The integrated design of microprocessor 210 allows relatively little additional circuitry to be used to create a small, dedicated computer system. PLD 290 complements microprocessor 210 by performing logical operations required by the microprocessor 210 or other circuitry of the device 103. ROM 280 stores configuration data that is initially loaded into PLD 290 on start-up. Similarly, EPROM 250 stores the initial code necessary to initialize and run microprocessor 210. Static RAM (SRAM) 240 is also connected to microprocessor 210, and is used for temporary program and data storage. Crystal oscillator 270 provides clocking signals to microprocessor 210 and PLD 290. In one implementation, crystal oscillator 270 generates a 50 MHz clock signal. Solid state storage device, such as Flash Memory 295 is connected to microprocessor 210 and used for long term memory storage.

Microprocessor 210 may control a number of external devices, such as LED status indicators 220 and a processor key lock 230. Through LED status indicators 220, microprocessor 210 may provide easily understandable feedback to a user. Processor key lock 230 is a physical interface through which a user must insert a physical key to enable microprocessor 210.

In addition to connecting to host 101 and drive 105 through interfaces 220 and 260, respectively, microprocessor 210 may be connected to external devices via RS-232 port 225 and RS-232 transceiver 260. RS-232 port 225 may be a standard DB9 connector that allows connections using a standard DB9 male to female serial cable.

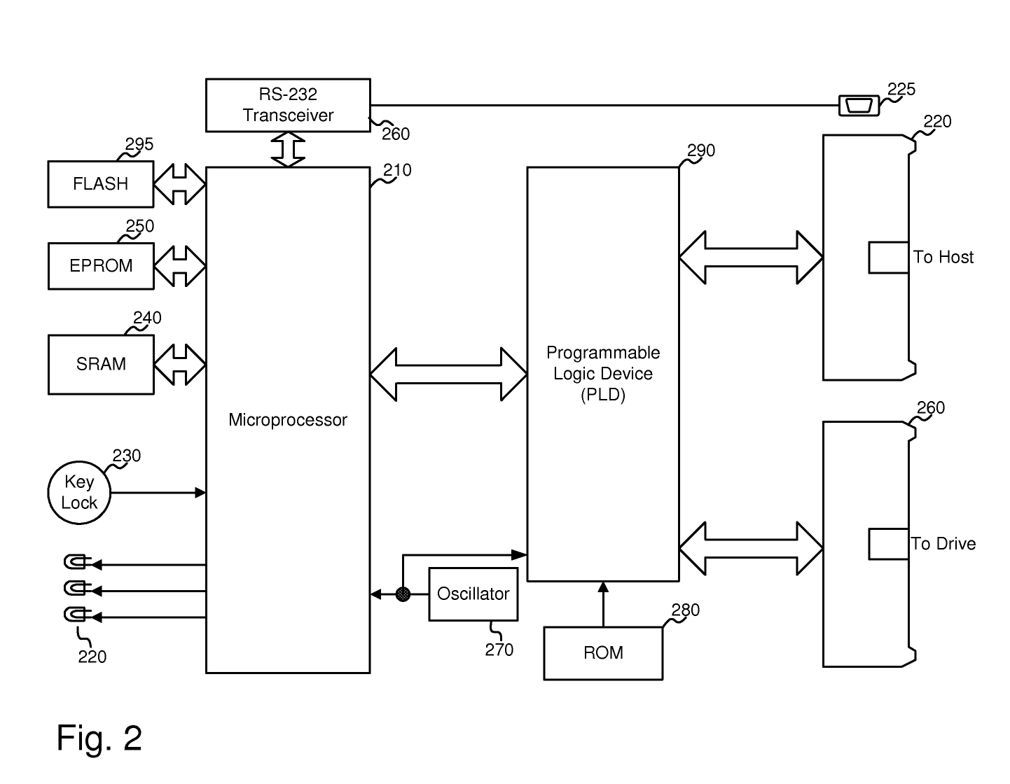

One of ordinary skill in the art will recognize that the components shown in FIG. 2 may be selected from a wide variety of commercially available components. In one implementation, the components in FIG. 2 may be selected as follows: PLD 290, part number EP 15KOQC208-2, available from Altera Corporation of San Jose, Calif.; ROM 280, part number EPC1PC8, available from Altera Corporation; EPROM 250, part number AT27LV020A90JC, available from Atmel Corporation, of San Jose, Calif.; and SRAM 240, part number CY7C1021V33L12ZCT, available from Cypress Corporation, of San Jose, Calif.

In one of its simplest embodiments, our invention can make a commercial off the shelf hard drive appear to the operating system to be a Write Once, Read Many (WORM) device.

Once the capabilities of the Drive is known to our device, it can make a decision as to how to provide this information to the Host. For this method, the Operating system is provided with data showing the Drive to be an Optical, Write Once device. This is done by responding to the Host that the Drive is not a Drive, but is a Packet Device such as a DVD Recorder. This spoofs the Host into treating the Drive as a Packet device. Our invention takes the Packet device commands and translates them into the appropriate hard drive commands, and vice versa. If the Host mistakenly tries to issue a command for a hard drive, our device may respond to the Host that the command has failed. A mistaken command from the Host is indistinguishable from an attack on the system, and our device protects the drives from any errant commands.

The previous discussion described the case where a hard drive device is spoofed by our device to appear to be a packet device. In some cases this is not required or desirable. By tracking the sectors written, our device may also present the drive to the Host as a drive, but reject all but the first write to a sector. Methods for rejecting write commands are detailed in our U.S. Pat. No. 6,813,682.

While the previous discussion has described a method of making the Operating System believe that the drive is an optical drive, this is not the only method available for Operating System transparency. One method would be to simply discard data from any write attempts to the drive to sectors that have already been written. This could use any of the techniques as described in U.S. Pat. No. 6,813,682.

### The Preferred Embodiment

The following detailed description of the preferred embodiment covers the case where it is desirable to have a hard drive emulate a write-once optical drive, such as a DVD-Recordable. Emulating a DVD-Recordable drive has the benefit of not requiring any special drivers for the operating system. The present invention provides the interface expected of the DVD-Recordable drive. Thus, an operating system such as Windows may treat the drive as a DVD-Recordable drive without any special software or installation process. Microsoft publishes a document (http://www.microsoft.com/whdc/device/storage/mmc_cd-dvd.mspx) that details the required commands for the native Windows drivers to properly operate a drive.

There is a certain advantage to having our device emulate an existing type of storage device rather than simply writing a set of new operating system drivers to support our device. If our device appears to an operating system to be a known, supported device, any software that follows the operating system's rules for accessing the device will work without modification. For instance, in the case where our device is emulating a DVD-Recordable drive, any standard DVD recording software should be able to access our device and properly write and read the desired data.

While the above discussion has centered on emulating a DVD-Recordable, this is for clarity of discussion. The current generation of DVD-Recordable drives have a maximum storage capability of only about 17 gigabytes (Assuming double sided dual layer), while a low cost hard drive might have 250 gigabytes of storage. If our present device required a 250 gigabyte hard drive in order to emulate a 17 gigabyte optical drive, it would not be particularly cost effective. One skilled in the art would see that our present invention is equally capable of emulating the next generation of DVD drives aimed at HDTV as well. With the HD-DVD disks at 30 Gigabytes and the Blue Ray disks at 50 Gigabytes, the gap between the optical drive capabilities and the hard drive capabilities narrows.

Although it is possible for our invention to emulate a DVD-Recordable drive and represent itself to be the size of a typical DVD-Recordable disk, there is another way to present the storage capabilities to the Host. One of the required functions for a DVD-Recordable device is the Read Capacity command. When this command is issued to a drive, it returns 4 bytes indicating the number of sectors that it is capable of supporting. (A sector is typically 512 bytes.) This 4-byte field allows the device to specify that it can support up to 2 Terabytes of data. By taking advantage of this field, our device is not restricted to the standard sizes typically used for DVD-Recordable media. Rather it can report its size as any convenient amount up to the actual size of the drive.

The same techniques that allow our device to emulate a DVD-Recordable drive can be used to have our device emulate a number of other types of storage devices. It is ideally suited for emulating a tape drive. Typically, tape drives have large amounts of storage that must be accessed linearly, and the access time is slow compared to a hard drive. An advantage to emulating a tape drive is that existing tape backup software, as used in most corporations, could immediately connect our unit to their system and continue using existing software and procedures. This gives them the benefit of tape like simplicity with hard drive speeds, and the security of the write once techniques embodied in the invention.

The present device has another security advantage over simply using an optical drive. There is nothing to prevent an optical drive from rewriting a previously written portion of its writeable media. A virus, operating system error, or malicious software can cause an optical drive to try and write any available sector. Should this happen, a loss of data would occur. The present invention protects already written data. In the preferred embodiment, software on the Host computer cannot cause a change to an already written portion of the drive.

Applicant's U.S. Pat. No. 6,813,682 teaches the use of non-volatile memory to contain user specified blocking areas for a hard drive. One of the enhancements embodied in the present invention is the source of the information for the blocking area. By tracking the sectors that have been written, our present device can build its own blocking area information in non-volatile memory without the need for user intervention. This technique allows the blocking area to be updated in real time as data is written to the drive.

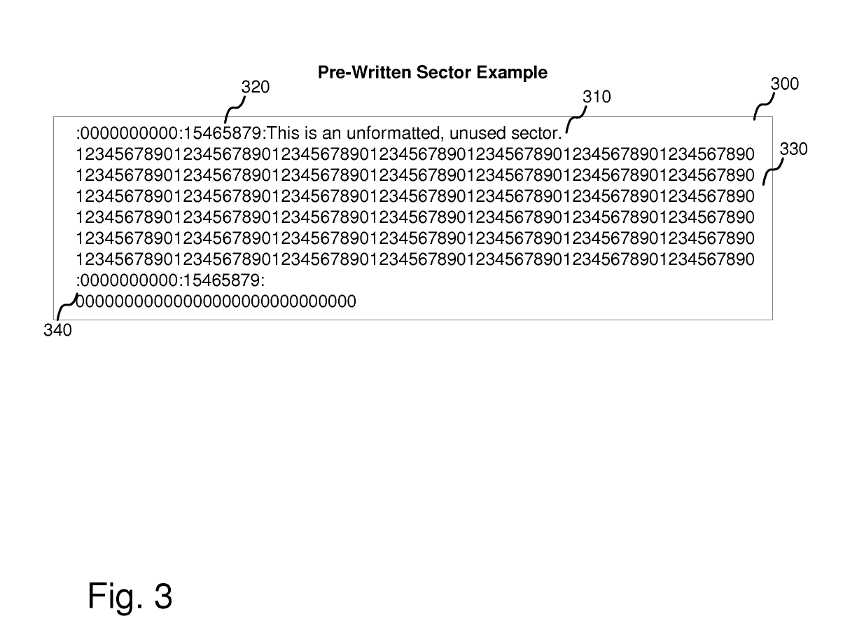

FIG. 3 shows an example of a Pre-Written sector of data, 300. In this example, there is a text field 310 with human readable words indicating that the sector is unused. Another field, 320, is a verification field, where data such as a checksum may be stored. Another verification field is at the end of the sector 340. This may be the same check as in 320 or it may be computed in a different fashion. Much of the sector stores known, bulk data 330. Having multiple different ways to check the authenticity of a Pre-Written sector allows for easy and fast-automated recovery in the case of a primary Flash failure.

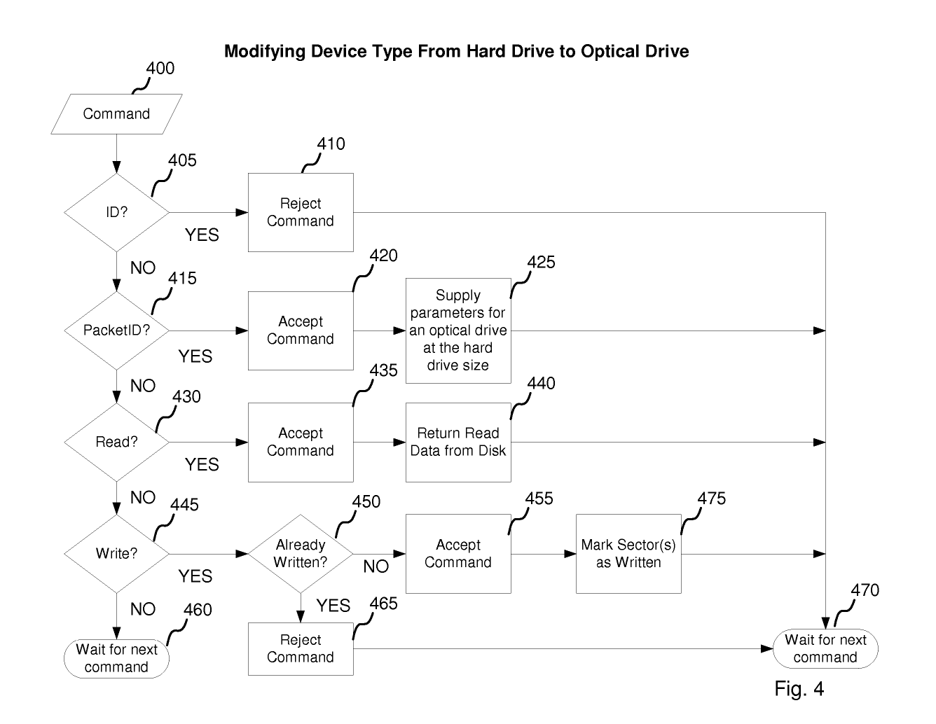

FIG. 4 illustrates one embodiment of logic flow that can make a hard drive behave like a write-once optical drive. When the host issues a command 400, the device examines the command to see how it should be processed. If the command is an Identify Device command 405 such as would be issued to get the operating parameters of a hard drive, the command would be rejected in the appropriate way to indicate the presence of a Packet Device 410. Typically, this would cause the Host to issue an Identify Packet Device request 415. When this command is presented, it is accepted 420 and processed 425. The parameters returned by this command match the capabilities of the drive as presented by the device. In most cases, the drive would be presented as its full size with the properties of a write once drive. Should the specific embodiment of the device require some storage space for its operations, the size presented would be the size of the drive minus the required storage space. For compatibility reasons, the drive would usually be presented as having removable media in addition to being an optical drive.

When a read command 430 is presented for processing, the command is accepted 435 and the data returned to the Host 440. A write command 445 requires additional processing. The requested sector or sectors to be written must be verified to be writeable 450. If a sector had been written before, the command would be rejected 465. On the other hand, if the requested sector(s) have not yet been written, the command will be accepted and the data written 455. The sector(s) will then be noted as having been written 475.

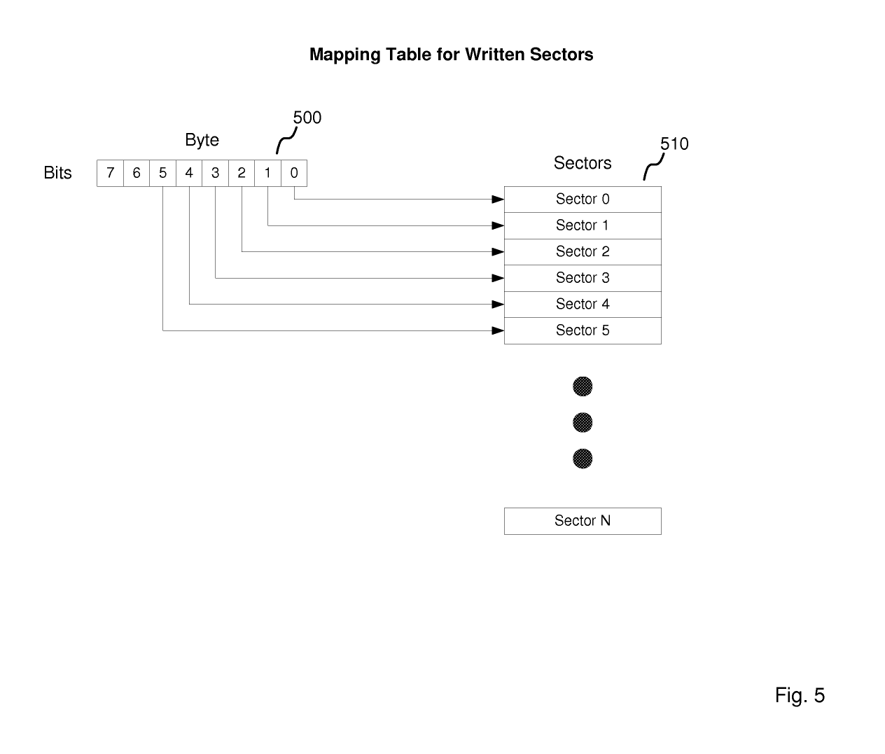

FIG. 5 illustrates one embodiment for tracking sectors written. In this method, one bit is used to represent a sector. In the preferred embodiment, the mapping of bits to sectors is done in a linear fashion. That is, Bit 0 of Byte 0 as shown in 500 maps to sector 0 as shown in 510. The benefit of this system is that a single bit in the Written Sectors table represents 512 bytes (4096 bits) of data.

If it were possible to know in advance that the sectors would be written in sequential order, an even more efficient method is available for determining which sectors have been written. All that would need to be stored is the number of the last sector written. For most SCSI based devices, this would be a single 32-bit number. Newer IDE devices may require 48 bits. Since this is a special case, it is not the preferred embodiment, but drivers could be written for the target operating system to allow such a method to work.

In cases where the amount of data to be stored can fit onto an optical disk, there is still an advantage in using the present invention instead of an optical drive. An optical drive may be instructed by the operating system to write a section of the drive that already contains data, thereby corrupting it. The invention prevents this from happening. Should a program intentionally or unintentionally try to write to an already written sector, the present invention will prevent the write from happening.

Tracking Written Areas

In order to emulate the Write-Only feature of an optical drive, our device tracks previously written sectors. In a simple embodiment, non-volatile memory, such as flash or magnetic core memory, is used for long-term storage of the previously written sector information. In order to track the sector usage of a typical 200-gigabyte drive using 512 byte sectors, less than 50 megabytes of storage space is required. This estimate of memory usage is for a worst case where it is necessary to track each sector individually. In reality, sectors would be written contiguously, as this is how it is typically done on an optical device. In such a case, all that our device needs to store are the ranges of sectors that have been written, or the ranges of free sectors, if that is more convenient. By storing ranges of sectors, the storage requirements drop dramatically. In a best case, only a single number would need to be stored; that of the last written sector.

In one embodiment, our device has a slot to insert standard non-volatile memory modules, such as a Compact Flash card, while in another embodiment the FLASH memory is soldered to the circuit board.

By having our device track the sectors written, there is no need for our device to understand a directory structure being used by the operating system. Whereas each drive format has different meanings for their bits indicating free or used space, it simply is irrelevant to our device. If our device has written a sector, it is logged and will not be written again. Should there be an attempt to write to a sector a second time, our device will either return status indicating that the command has failed, or return status that the command has succeeded and discard the data from the write attempt.

This is one of the methods of maintaining Operating System independence. By being operating system independent, our device works equally well when connected to PC as it does when connected to a NAS or SAN device. Operating System independence insures that our device is compatible with all current and future host types that support the physical interface and protocols, regardless of changes in the underlying file structures.

Selectively Delete

In another embodiment, there is a need to be able to change data that has been previously written to the Drive. Applicant's pending patent Ser. No. 10/765,526 teaches techniques for having additional interfaces on a drive protection device. In this embodiment, another interface is included in our device that has the ability to communicate with a Host, though not necessarily the same Host. Through this interface, data may be changed on the drive. The extent and nature of the changes would depend on the embodiment, but typically it would be full change access to the Drive. Having this second interface allows for a measure of physical security for the device. If this interface is connected to a Host that is not connected to a network, there is no method for remote attacks. At the same time, the protected data could be connected to an Internet facing Host, and would be immune from all external attacks.

Protecting Written Area's Information

Since the written sector information is vitally important to maintaining the integrity of the data, multiple methods are available to protect the information. The amount of information varies among the different embodiments, so the preferred method of backup/protection of the data may vary as well. Along with the sector information, the information to be protected may include drive information. In the case of a complete hardware failure, drive information, such as the drive's serial number, would help match the written sector information with the drive.

In one embodiment, a method is provided to communicate the contents of the written sector information to another device or location. One example would be to include an interface for a long-term storage device for a producing a backup of the written sector list. The user would simply connect a long-term storage device, such as a compact flash card, to this interface, and the written sector information would be copied automatically. In another embodiment, the user would indicate that our invention should copy the data using one or more controls on our device.

In another embodiment, the written sector information may be stored on the drive itself. In the worst case, the amount of storage required for the written sector list is tiny compared to the amount of storage provided by the drive. The amount is about 1/4000 the size of the drive is required for the written sector information. That comes out to about 250 bytes per million bytes of storage. This is a small enough amount that it could easily be borrowed from the drive itself. Since our device reports the capabilities of the drive to the Host in a slightly modified way, it may also report the size of the drive to be a little smaller than it actually is. Doing so frees some room on the drive to store a copy, or even the master version, of the written sector information. The written sector information may even be stored in a compressed format to save on the storage requirements.

In another embodiment, an interface can be provided on the device for save the written sector information to another long term storage device, such as a Compact Flash card. In one embodiment, when it is detected that a card is connected to the interface, the written sector information is copied to the card along with data identifying the drive and any settings that might be useful for recovering from a failure.

In another embodiment, the data transfer would not start until initiated by the user, either electronically or mechanically.

In another embodiment, the written sector information would be continuously updated on the additional long-term memory device as long as it remained connected to our device or until our device is signaled to stop the updates.

For additional security and protection against hardware failures, different methods of storing the written sector information may be combined. Combining the method of storing the written sector information in FLASH within our device and storing a copy on the drive insures that in the event of a failure of our device, another working unit of our device may continue to provide protection to the drive. In the case, of a failure of our device and the specific embodiment uses removable memory for its written sector list storage, the removable memory may simply be moved to the new, working unit.

In another embodiment, the Drive may be preformatted to have a unique identifier stored on each sector. Once a sector is written, the data on the sector will not match the expected data from the preformatting. In the case of a failure of our device, a working unit of our device could scan the entire drive and rebuild the written sector information without requiring any information from the failed unit. Using this method as the main technique for determining the whether sectors had already been written would not be the best idea, as it requires a read before write of every sector.

Any of the methods may be used individually, but the highest level of security and disaster recovery comes from using multiple techniques, such as combining the preformatting technique with removable FLASH storage.

Protected Drive spoofed as Removable Drive

One technique that is similar to the Optical Drive method previously described is to treat the drive as a removable drive. One feature of removable drives is that they are allowed to be write protected. In this case, it is possible to accept data writes for previously unwritten sectors. Once a sector has been written, it is possible to respond to a subsequent write attempt with a Command Aborted response with Write Protected as the reason.

Multiple Drives

In another embodiment, our invention can support multiple drives at once. In the case of an IDE drive, it is typical for two drives to be able to be controlled through a single cable. SCSI drives may have even more drives on a cable. Our device can be designed to support from one drive up to the maximum number of drives supported by the interface.

In another embodiment, our device can control multiple drives, but report to the host that it is a single drive. From the point of view of the Host, this embodiment allows for the creation of a larger drive out of two or more drives. For instance, a pair of 250 Gig drives could be presented to the host as a single 500 Gig drive. The drives would not have to be identical, or matched in any way. A 100 Gig drive could be combined with a 300 Gig drive for a total of 400 Gigs. All of this is transparent to the host, as it sees just a single drive that is the combination of the two or more drives attached to our device.

In the case of interfaces that support multiple drives, it is possible to create a version of our device that supported joining drives and presents multiple larger drives to the host. This is especially important in SCSI implementations as there is a very real and attainable size limit for SCSI drives. The limit for most SCSI devices is about 2 Terabytes per drive, which only takes four or five low cost drives to reach.

Different Interfaces

In another embodiment, our device can present a different interface to the Host than it uses to control the drive(s). In this way, low cost IDE or SATA drives can be connected to our device, while our device uses a SCSI interface to connect to the Host.

RAID

Since there is no particular limit to the number of drives that our device can support, a number of interesting options are available to different embodiments. Since our device acts as the controller to its drives and may present any type of standard interface to the Host, there is a great deal of flexibility in how our device manages and presents its drives. Drives may be combined to act as a RAID subsystem, while presenting a single interface to the Host.

Multiple Interfaces

In another embodiment, our device can present two or more interfaces to the Host. Since each interface has its own bandwidth limitations, there is a benefit to being able to use more than one Host interface to maximize system resources. There is no need for the Host interfaces to be the same. Our device may use multiple, different interfaces for communicating to the Host. It is not unreasonable to have both IDE and SCSI interfaces on the same device. In some embodiments, these may be able to be used simultaneously.

Initialize Sector Data

Our invention needs to track the sectors that are written to the drive in order to avoid overwriting them. Some method needs to be provided to Initialize the sector information, either when first installed or at some later time. While there are many techniques that could be used, such as accepting the Initialize command from the Host, this would make it too easy for an unauthorized user to remotely modify the data on the protected drive. Using an auxiliary port on our device, such as a USB port, a user with physical access to our device can instruct it to reset the sector information. [described in Side Port application].

In the case where a user communicates with our device through an auxiliary port, in one embodiment certain commands, such as resetting the written sector information would require the use of a password. As it is important that only authorized users be able to modify the written sector information, many other security techniques may be used either in addition or instead of the password. For instance, in one embodiment, our device has a biometric scanner, such as one for fingerprints, as its authorization method. One skilled in the art would realize that any number of other biometric, visual, password, passkey and even physical security measures may be used to control access to our device.

Removable Drive Bay for Copying

As our device may control quite a number of drives simultaneously, should the particular embodiment require it, another embodiment allows for the automatic backup of any of the drives connected to our device. In the preferred embodiment, a removable drive bay is provided so that the user may connect a new drive to our device for the copy. Through an interface, either electrical or mechanical, the user may specify which drive or drives should be copied to the drive in the bay.

Depending on the priority assigned to the copying process, there would be a very minimal impact on system performance. Our device can analyze the traffic between the Host and itself, and intersperse its read requests with the Host's. If there is a lot of traffic on the bus, our device may use the data that is about to be sent to the Host and also write it to the drive in the bay. This would have virtually no impact on system performance, but would not guarantee that the entire drive would be copied in a timely fashion. Any sectors that were not copied in this fashion would be read a a later point based on the priority assigned to the copy process.

Between this technique and the techniques described above, a drive protected with our invention is far more secure than one without.

### SUMMARY

As described above, a blocking device is inserted between a host computer system and a storage device. The blocking device tracks areas of the storage device that have previously been written to. The blocking device blocks certain commands from being sent to the storage device, such as write commands addressed to a previously written area of the storage device. An embedded processor within the blocking device controls functionality of the blocking device. The functionality of the embedded processor can be programmably modified to allow for a number of different possible blocking options.

Although the blocking device has been primarily described as blocking write commands, one of ordinary skill in the art will appreciate that the blocking device could instead or additionally block read commands.

It will be apparent to one of ordinary skill in the art that the embodiments as described above may be implemented in many different forms of software, firmware, and hardware in the implementations illustrated in the figures. The actual software code or specialized control hardware used to implement aspects consistent with the present invention is not limiting of the present invention. Thus, the operation and behavior of the embodiments were described without specific reference to the specific software code, it being understood that a person of ordinary skill in the art would be able to design software and control hardware to implement the embodiments based on the description herein.

The foregoing description of preferred embodiments of the present invention provides illustration and description, but is not intended to be exhaustive or to limit the invention to the precise form disclosed. Modifications and variations are possible in light of the above teachings or may be acquired from practice of the invention.

No element, act, or instruction used in the description of the present application should be construed as critical or essential to the invention unless explicitly described as such. Also, as used herein, the article “a” is intended to include one or more items. Where only one item is intended, the term “one” or similar language is used.

The scope of the invention is defined by the claims and their equivalents.

What is claimed is:

1. A write-once, read many blocking device comprising:
an interface emulator configured to emulate an interface presented by a storage device and configured to connect to a host;
an interface for connecting to the storage device;
long term memory; and
a processor coupled to the interface emulator, interface and the long term memory, the processor maintaining a list of areas written to the storage device in the long term memory, the processor examining commands received through the interface emulator that are generated by the host and intended for the storage device, the processor allowing only those of the commands that match a predetermined set of commands to pass to the storage device via the interface, the predetermined set of commands being commands that are known to be safe for the particular storage device's application and do not change the state of areas previously written to, wherein the blocking device is transparent to normal operation of the host and the storage device.

2. The write-once, read many blocking device of claim 1, wherein the interface is an integrated device electronics (IDE) interface for a disk drive.

3. The write-once, read many blocking device of claim 1, wherein the processor receives data back from the storage device in response to the commands passed to the storage device and forwards the received data to the host through the interface emulator.

4. The write-once, read many blocking device of claim 3, wherein, when the commands include a capabilities request command relating to the storage device, the processor modifies data received from the storage device relating to the capabilities request command to reflect the capability of the storage device as affected by the presence of the blocking device.

5. The write-once, read many blocking device of claim 1, wherein the processor drops those of the commands that do not match the predetermined set of commands, and, after dropping one of the commands, returns status information to the host that indicates that the dropped command was successfully completed.

6. The write-once, read many blocking device of claim 1, further comprising: additional interfaces for connecting to additional storage devices.

7. The write-once, read many blocking device of claim 6, wherein each of the interfaces is independently coupled to the processor.

8. The write-once, read many blocking device of claim 1, further including light emitting diodes (LEDs) coupled to the processor and configured to transmit status information relating to the status of the blocking device.

9. The write-once, read many blocking device of claim 1, further including: a temporary storage device coupled to the processor, the processor storing data from the host corresponding to at least one command that does not match the predetermined set of commands in the temporary storage device.

10. The write-once, read many blocking device of claim 9, wherein when read commands are received from the host that refer to data stored in the temporary storage device, the processor returns the data from the temporary storage device to the host.

11. The write-once, read many blocking device of claim 1, wherein the processor examines feature information from the storage device that relate to features supported by the storage device and the processor zeroes any features not supported by the processor before making the feature information available to the host.

12. The write-once, read many blocking device of claim 1, wherein the processor supports a removable drive feature set with the host and the processor returns a write protected error code to the host when the processor drops one of the commands.

13. The write-once, read many blocking device of claim 1, wherein a failure results in all write attempts to the storage device being blocked.

14. The write-once, read many blocking device of claim 1, wherein the data in the long term storage is available to another device to take a “snap shot” of the long term storage device at a particular time.

15. The write-once, read many blocking device of claim 14, wherein the data is used to facilitate making a copy of the long-term storage device.

16. The write-once, read many blocking device of claim 1, further comprising: a second interface emulator configured to emulate an interface presented by a storage device and configured to connect to a host.

17. The write-once, read many blocking device of claim 16, wherein the processor allows coming from the second interface emulator to change the state of areas previously written to.

18. A device comprising:
an IDE emulator component, the IDE emulator component including a physical interface designed to engage a first cable that connects to a host that controls an IDE storage device;
an IDE interface configured to engage a second cable that connects to the IDE storage device;
a long term memory component; and
a logic circuit connecting the IDE emulator component, the IDE interface, and the long term memory component and configured to: maintain a list of areas written to the IDE storage device in the long term memory component, compare commands received at the IDE emulator component to a predetermined set of commands, and to allow transmission of the commands from the IDE emulator component to the IDE interface when the comparison indicates that the received command is in the predetermined set of commands and does not modify the state of an area previously written to, wherein
the device operates transparently to normal operation of the host and the IDE storage device.

19. The device of claim 18, wherein the logic circuit includes:
an embedded processor,
a computer memory connected to the embedded processor, the embedded processor loading program instructions from the computer memory during device initialization, and
a programmable logic device (PLD) coupled to the embedded processor, the IDE emulator component, and the IDE interface.

20. The device of claim 19, wherein the PLD includes:
a bus driver component configured to transfer data between the embedded processor, the IDE emulator component, and the IDE interface,
a first dual port memory buffer connected between the bus driver and the IDE interface,
a first set of communication lines connecting the bus driver directly to the IDE interface and indirectly to the IDE interface through the first dual port memory buffer,
a second dual port memory buffer connected between the bus driver and the IDE emulator component, and
a second set of communication lines connecting the bus driver directly to the IDE emulator component and indirectly to the IDE emulator component through the second dual port memory buffer.

21. A method comprising:
intercepting communications between a computer motherboard and a local non-volatile storage device for the motherboard;
maintaining a list of areas written to on the non-volatile storage device;
comparing commands in the communications between the motherboard and the storage device to a predetermined set of commands;
forwarding selected ones of the commands to the storage only when, based on the comparison, the commands are determined to be commands that are in a predetermined set of commands known to be safe for the particular storage device's application and do not change the state of an area previously written to; and
blocking other commands from being received by the storage device, wherein
the intercepting communications, comparing commands, forwarding selected ones of the commands, and blocking selected other ones of the commands is transparent to normal operation of the computer motherboard and the storage device.

22. The method of claim 21, further comprising:
forwarding data from the storage device to the motherboard in response to a read command received from the motherboard and forwarded to the storage device.

23. The method of claim 21, wherein the storage device is an integrated device electronics (IDE) disk drive.

24. The method of claim 21, wherein the commands forwarded to the storage device include a capabilities request command, the method further comprising:
modifying data received from the storage device relating to the capabilities request command to reflect the capability of the storage device as modified by operation of the method.

25. The method of claim 24, further comprising, after blocking a command:
returning status information to the motherboard that indicates that the blocked command was successfully executed by the storage device.

26. A computer system comprising:
a host computer;
a long-term storage device; and
a write-once, read many blocking device coupled between the host computer and the storage device, the write-once, read many blocking device configured to:
intercept commands from the host to the storage device,
maintain a list of areas written to on the storage device,
pass commands to the storage device only when the commands are in a predetermined set of commands that are known to be safe for the particular storage device's application and do not change the state of areas previously written to, and
block other commands from reaching the storage device,
wherein the intercepting commands, blocking commands, and passing commands are performed by the blocking device transparently to the host computer and the long-term storage device.

27. The computer system of claim 26, wherein the blocking device further includes:
an interface emulator configured to emulate the storage device to the host
long term memory; and
an interface configured to connect the blocking device to the storage device.

28. The computer system of claim 27, wherein the interface emulator emulates an Integrated Device Electronics (IDE) interface and the storage device is an IDE disk drive.

29. The computer system of claim 26, wherein the blocking device receives data back from the storage device in response to one of the passed commands and forwards the received data to the host.

30. The computer system of claim 26, wherein, when the passed commands include a capabilities request command relating to the storage device, the blocking device modifies data received from the storage device relating to the capabilities request command to reflect the capability of the storage device as affected by the presence of the blocking device.

31. The computer system of claim 26, wherein the blocking device, after blocking one of the commands, returns status information to the host that indicates that the blocked command was successfully completed.

32. The computer system of claim 26, wherein the blocking device further includes light emitting diodes (LEDs) configured to transmit status information relating to the status of the blocking device.

33. The computer system of claim 26, wherein the blocking device further includes:
a temporary storage device, the blocking device storing data from the host corresponding to blocked commands in the temporary storage device.

34. The computer system of claim 33, wherein when read commands are received from the host that refer to data stored in the temporary storage device, the blocking device returns the data from the temporary storage device to the host.

35. The computer system of claim 26, wherein the blocking device further includes:
a user configurable memory, the user configurable memory storing instructions that define protected areas on the storage device, the blocking device dropping those of the commands that would otherwise modify the protected areas on the storage device.

36. A write-once, read many blocking device comprising:
means for intercepting communications between a host and a storage device;
means for maintaining a record of areas written to on the storage device;
means for comparing commands in the communications between the host and the storage device to a predetermined set of commands;
means for forwarding selected ones of commands in the intercepted communications to the storage device only when, based on the comparison, the commands that are in a predetermined set of commands are determined to be safe for the particular storage device's application and do not modify the state of an area previously written to; and
means for blocking other ones of the commands from being received by the storage device based on the comparison, wherein
the blocking device operates transparently to normal operation of the host and the storage device.

37. The blocking device of 36, wherein the storage device is an integrated device electronics (IDE) disk drive.

38. The blocking device of 36, wherein the commands forwarded to the storage device include a capabilities request command, and the means for forwarding further comprises:
means for modifying data received from the storage device relating to the capabilities request command to reflect the capabilities of the blocking device.

39. The write-once, read many blocking device of 36, further comprising:
means for returning status information to the host that indicates that the blocked command was successfully executed by the storage device.

40. The write-once, read many blocking device of claim 2, wherein the interface emulator is configured to emulate an IEEE 1394 connection.

41. The write-once, read many blocking device of claim 1, wherein the commands that are known to be safe for the particular storage device's application do not include a format drive command.

42. The write-once, read many blocking device of claim 1, wherein the commands that are known to be safe for the particular storage device's application do not include a change password command.

43. The write-once, read many blocking device of claim 1, wherein the commands that are known to be safe for the particular storage device's application include only commands that are in the published specifications for the storage device.

44. The write-once, read many blocking device of claim 1, wherein there are means for a user to change the predetermined list of commands.

45. The write-once, read many blocking device of claim 1, wherein the write-once, read many blocking device may substitute an equivalent command to send to the storage device for a command in the list of commands that are known to be safe for the particular storage device's application.
